(19) United States
(12) Patent Application Publication
(10) Pub. No.: US 2024/0397759 A1
(43) Pub. Date: Nov. 28, 2024

(54) DISPLAY PANEL AND DISPLAY DEVICE

(71) Applicant: WUHAN TIANMA MICRO-ELECTRONICS CO., LTD., Hubei (CN)

(72) Inventors: Lei WANG, Hubei (CN); Hao DAI, Hubei (CN); Meihong WANG, Hubei (CN); Yangzhao MA, Hubei (CN)

(73) Assignee: WUHAN TIANMA MICRO-ELECTRONICS CO., LTD., Hubei (CN)

(21) Appl. No.: 18/029,588

(22) PCT Filed: Apr. 21, 2022
(86) PCT No.: PCT/CN2022/088114

§ 371 Date: Mar. 30, 2023

(30) Foreign Application Priority Data
Feb. 9, 2022 (CN) 202210121502.4

(51) Int. Cl. H10K 59/124; H10K 59/122; H10K 59/35

(52) U.S. Cl. CPC H10K 59/124; H10K 59/122; H10K 59/353

(57) ABSTRACT

Provided are a display panel and display device. The display panel includes an optical component area, where the optical component area includes a substrate, an insulating layer and a first electrode. The insulating layer includes a first insulating layer and a second insulating layer, the second insulating layer is located on a side of the first insulating layer facing away from the substrate, and the first insulating layer includes a first insulating sub-layer in contact with the second insulating layer. The first electrode is located on a side of the second insulating layer facing away from the substrate, and the first insulating sub-layer is provided with at least one first insulating opening. In the thickness direction of the display panel, the second insulating layer covers the at least one first insulating opening, and the first electrode and the at least one first insulating opening at least partially overlap.

### CROSS-REFERENCE TO RELATED APPLICATION(S)

The present application claims priority to a Chinese patent application No. 202210121502.4 filed on Feb. 9, 2022, disclosure of which is incorporated herein by reference in its entirety.

### TECHNICAL FIELD

Embodiments of the present application relate to the field of display technologies, for example, a display panel and a display device.

### BACKGROUND

With the development of electronic products including display panels and cameras, such as mobile phones, the requirements of people for these products have not only been limited to basic communication functions, but also turned to design, artistry and good visual experience. For example, electronic products with high screen-to-body ratios are becoming more and more popular. Among them, the full screen has become an important development direction of electronic products. The earpiece, ambient light sensor, and proximity light sensor have all been successfully hidden under the screen, but the front-facing camera is difficult to hide.

To achieve the true full screen, the front-facing camera may be set under the screen. However, there are many problems to be solved urgently for the full screen with the front-facing camera set under the full screen.

### SUMMARY

In a first aspect, an embodiment of the present application provides a display panel. The display panel includes an optical component area.

The optical component area includes a substrate, an insulating layer and a first electrode.

The insulating layer includes a first insulating layer and a second insulating layer, the second insulating layer is located on a side of the first insulating layer facing away from the substrate, and the first insulating layer includes a first insulating sub-layer in contact with the second insulating layer.

The first electrode is located on a side of the second insulating layer facing away from the substrate; the first insulating sub-layer is provided with at least one first insulating opening; and in the thickness direction of the display panel, the second insulating layer covers the at least one first insulating opening, and the first electrode and the at least one first insulating opening at least partially overlap.

In a second aspect, based on the same inventive concept, an embodiment of the present application further provides a display device including the display panel described in the first aspect.

### BRIEF DESCRIPTION OF DRAWINGS

FIG. 1 is a structural diagram of a display panel in the related art;

FIG. 2 is an enlarged view of part A of FIG. 1;

FIG. 3 is a sectional view taken along direction B-B′ of FIG. 2;

FIG. 4 is a structural diagram of a display panel according to an embodiment of the present application;

FIG. 5 is an enlarged view of part C of FIG. 4;

FIG. 6 is a sectional view taken along direction D-D′ of FIG. 5;

FIG. 7 is another sectional view taken along direction D-D′ of FIG. 5;

FIG. 8 is another sectional view taken along direction D-D′ of FIG. 5;

FIG. 9 is another sectional view taken along direction D-D′ of FIG. 5;

FIG. 10 is another sectional view taken along direction D-D′ of FIG. 5;

FIG. 11 is another sectional view taken along direction D-D′ of FIG. 5;

FIG. 12 is another sectional view taken along direction D-D′ of FIG. 5;

FIG. 13 is another sectional view taken along direction D-D′ of FIG. 5;

FIG. 14 is a sectional view taken along direction E-E′ of FIG. 5;

FIG. 15 is another sectional view taken along direction E-E′ of FIG. 5;

FIG. 16 is a sectional view taken along direction F-F′ of FIG. 5;

FIG. 17 is another sectional view taken along direction F-F′ of FIG. 5;

FIG. 18 is another sectional view taken along direction D-D′ of FIG. 5;

FIG. 19 is another sectional view taken along direction D-D′ of FIG. 5;

FIG. 20 is another enlarged view of part C of FIG. 4;

FIG. 21 is a sectional view taken along direction G-G′ of FIG. 20;

FIG. 22 is another sectional view taken along direction E-E′ of FIG. 5;

FIG. 23 is a structural diagram of a display device according to an embodiment of the present application; and

FIG. 24 is a sectional view of a display device according to an embodiment of the present application.

### DETAILED DESCRIPTION

The present application is further described in detail in conjunction with the drawings and the embodiments. It is to be understood that the embodiments set forth below are intended to illustrate and not to limit the present application. Additionally, it is to be noted that for ease of description, only part, not all, of structures related to the present application are illustrated in the drawings.

It is apparent for those skilled in the art that various modifications and changes in the present application may be made without departing from the spirit or scope of the present application. Accordingly, the present application is intended to cover modifications and variations of the present application that fall within the scope of the appended claims (the claimed technical schemes) and their equivalents. It is to be noted that the implementations provided by the embodiments of the present application, if not in collision, may be combined with one another.

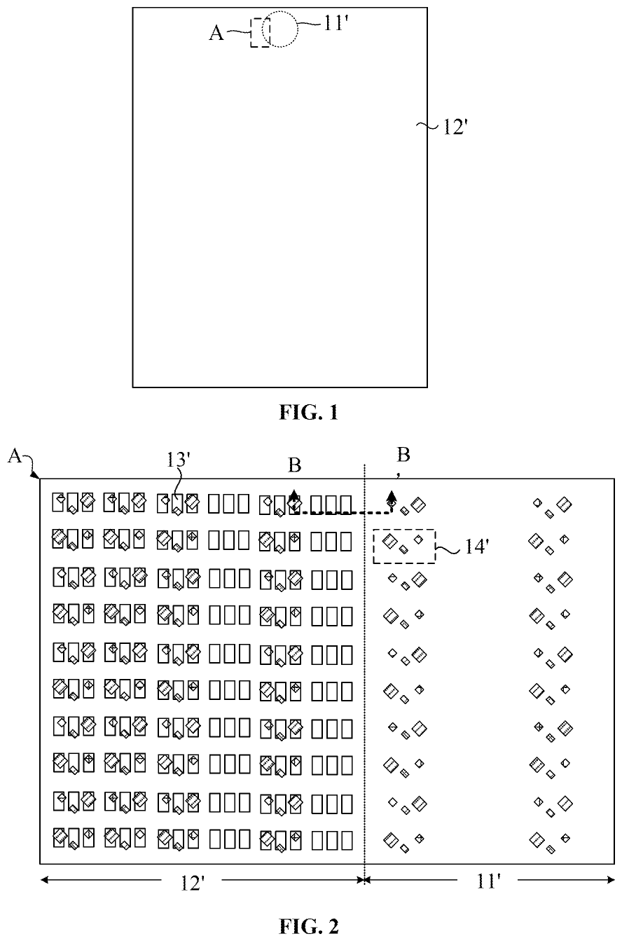

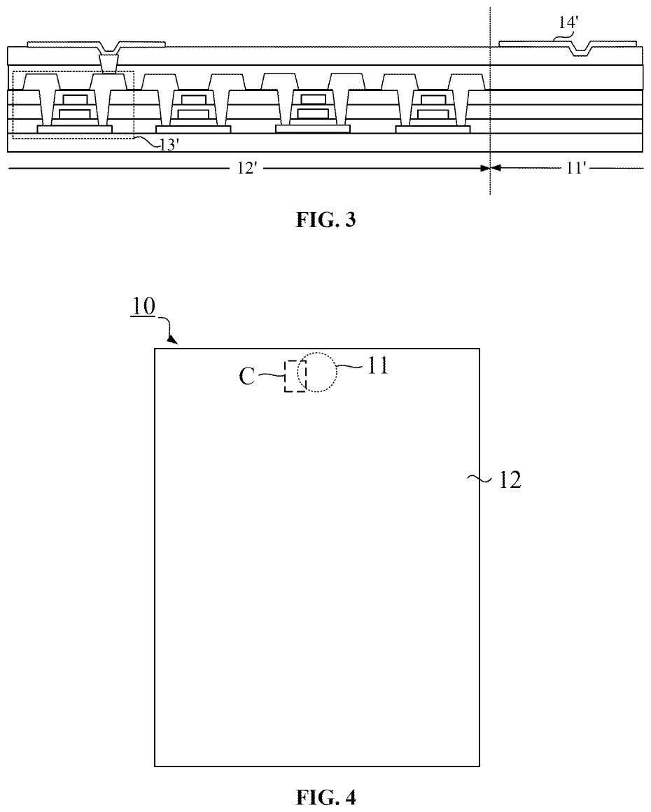

FIG. 1 is a structural diagram of a display panel in the related art. FIG. 2 is an enlarged view of part A of FIG. 1. FIG. 3 is a sectional view taken along direction B-B′ of FIG. 2. As shown in FIGS. 1 to 3, the display panel in the related art includes an optical component area 11′ and a normal display area 12′. The optical component area 11′ may be multiplexed as a sensor reserved area such as a camera reserved area. Therefore, in addition to having a normal display function, the optical component area 11′ has a good light-transmissive effect, ensuring that external light can transmit through the optical component area 11′ to enter a camera. Since pixel circuits 13′ are main light blocking elements in the display area of the display panel, to ensure the good light-transmissive effect of the optical component area 11′, the area ratio of pixel circuits 13′ in the optical component area 11′ may be smaller than the area ratio of pixel circuits 13′ in the normal display area 12′. For example, the pixel circuits are disposed in the optical component area in a smaller density than in the normal display area (and/or disposition densities of the pixel circuits in the optical component area and the normal display area are the same, but the area of a single pixel circuit in the optical component area is smaller than the area of a single pixel circuit in the normal display area), that is, the pixel circuits in the optical component area are in a built-in type (not shown in the figure). Alternatively, no pixel circuits 13′ are disposed in the optical component area 11′, that is, the pixel circuits in the optical component area are in a built-out type, as shown in FIGS. 2 and 3. In the display panel, the pixel circuit 13′ is configured to drive a light-emitting element 14′ to emit light.

However, the applicant has found that when the area ratio of the pixel circuits 13′ in the optical component area 11′ is smaller than the area ratio of the pixel circuits 13′ in the normal display area 12′, or when no pixel circuits 13′ are disposed in the optical component area 11′, heat dissipation films in the optical component area 11′ are reduced, affecting the heat dissipation capability of the optical component area 11′. That is, the optical component area 11′ may have poor heat dissipation capability, which may affect the light-emitting effect of the light-emitting element in the optical component area 11′ and affect the normal display of the display panel.

In the embodiments of the present application, a display panel includes an optical component area, where the optical component area includes a substrate, an insulating layer and a first electrode. The insulating layer includes a first insulating layer and a second insulating layer, the second insulating layer is located on a side of the first insulating layer facing away from the substrate, and the first insulating layer includes a first insulating sub-layer in contact with the second insulating layer. The first electrode is located on a side of the second insulating layer facing away from the substrate, the first insulating sub-layer is provided with at least one first insulating opening. In a thickness direction of the display panel, the second insulating layer covers the first insulating opening, and the first electrode and the first insulating opening at least partially overlap. In the above schemes, the first insulating opening is provided so as to reduce the interface thermal resistance between films in the optical component area, improving the heat dissipation capability of the optical component area. Moreover, in the thickness direction of the display panel, the first electrode and the first insulating opening at least partially overlap, that is, the first electrode covers at least part of the first insulating opening. In this manner, heat generated in the operating process of the first electrode can be dissipated in time, preventing a display device in the display panel from aging, and moreover, improving the display reliability of the optical component area. Moreover, the first electrode covers at least part of the first insulating opening so that no apparent light-transmissive difference in different areas of the optical component area can be caused due to the setting of the first insulating opening, ensuring the light-transmissive effect of the optical component area to be balanced and good.

The above is the core idea of the present application. Schemes in the embodiments of the present application will be described clearly and completely in conjunction with the drawings in the embodiments of the present application.

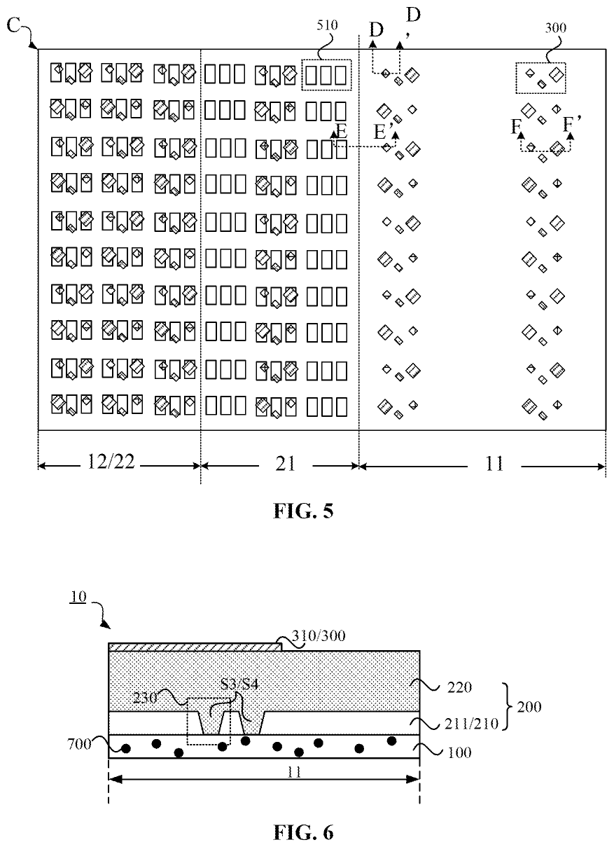

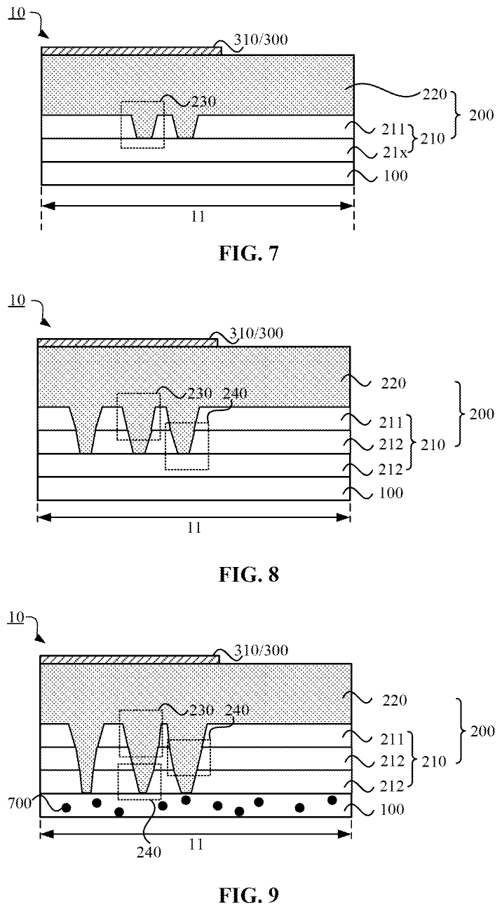

FIG. 4 is a structural diagram of a display panel according to an embodiment of the present application. FIG. 5 is an enlarged view of part C of FIG. 4. FIG. 6 is a sectional view taken along direction D-D′ of FIG. 5. FIG. 7 is another sectional view taken along direction D-D′ of FIG. 5. As shown in FIGS. 4, 5, 6 and 7, a display panel 10 provided by the embodiment of the present application includes an optical component area 11, and the optical component area 11 includes a substrate 100, an insulating layer 200, and a first electrode 310. The insulating layer 200 includes a first insulating layer 210 and a second insulating layer 220, the second insulating layer 220 is located on a side of the first insulating layer 210 facing away from the substrate 100, and the first insulating layer 210 includes a first insulating sub-layer 211 in contact with the second insulating layer 220. The first electrode 310 is located on a side of the second insulating layer 220 facing away from the substrate 100; the first insulating sub-layer 211 is provided with at least one first insulating opening 230; and in the thickness direction of the display panel 10, the second insulating layer 220 covers the first insulating openings 230, and the first electrode 310 and the first insulating openings 230 at least partially overlap.

For example, as shown in FIG. 4, the display panel provided by the embodiment of the present application may be applicable to a display device including a sensor disposed under a screen. The display panel 10 includes the optical component area 11. The optical component area 11 may be used as the disposition area for optical components, where the optical components may be a camera, an infrared sensor and another device. The embodiment of the present application is not limited thereto. For example, the display panel 10 provided by the embodiment of the present application may also include a normal display area 12. The normal display area 12 may be used as a normal display area in the display panel 10, that is, be used without having a large light-transmissive rate.

For example, as shown in FIGS. 5 to 7, the display panel 10 may include light-emitting elements so that the display effect of the display panel 10 can be ensured. The light-emitting element may be an Organic Light-Emitting Diode (OLED). The light-emitting elements may include first light-emitting elements 300 located in the optical component area 11. The first light-emitting element 300 includes a first electrode 310 that generates heat when the first light-emitting element 300 is normally operating. For example, the first electrode 310 may be a first anode, or may be another pixel electrode such as a cathode. The embodiment of the present application is not limited thereto. As shown in FIG. 5, the distribution density of the first light-emitting elements 300 in the optical component area 11 may be smaller than the distribution density of the light-emitting elements in the normal display area 12. It is to be noted that in other exemplary implementations, the distribution density of the first light-emitting elements in the optical component area 11 may be equal to the distribution density of the light-emitting elements in the normal display area 12. The present application is not limited thereto.

For example, the optical component area 11 further includes the insulating layer 200 and the substrate 100. In the thickness direction of the display panel 10, the insulating layer 200 is located above the substrate 100, and the first electrode 310 is located on a side of the insulating layer 200 facing away from the substrate 100. The insulating layer 200 includes a first insulating layer 210 and a second insulating layer 220, where the first insulating layer 210 faces the substrate 100 and the second insulating layer 220 faces away from the substrate 100. Here, the first insulating layer 210 includes a first insulating sub-layer 211, where part of the first insulating sub-layer 211 may be removed from the first insulating sub-layer 211 to prepare at least one first insulating opening 230. In FIGS. 6 and 7, the case where two first insulating openings 230 are provided is taken as an example. The number of first insulating openings 230 is not limited in the embodiments of the present application. For example, as shown in FIG. 6, the first insulating layer 210 may include only the first insulating sub-layer 211. As shown in FIG. 7, the first insulating layer 210 may include other insulating sub-layers 21x in addition to the first insulating sub-layer 211. The first insulating sub-layer 211 is closer to the second insulating layer 220 than the other insulating sub-layers. The first insulating sub-layer 211 is provided with the at least one first insulating opening 230, and moreover, the second insulating layer 220 covers the at least one first insulating opening 230. In this manner, isolation interfaces between different films in the area where the first insulating openings 230 are located can be eliminated, the interface thermal resistance of the heat conduction between another film (the film located on a side of the first insulating sub-layer facing the substrate) and the second insulating layer 220 can be reduced, and the heat conduction capability in the area where the first insulating openings 230 are located can be increased. Moreover, in the thickness direction of the display panel, the first electrode 310 at least partially overlaps the first insulating openings 230, that is, the first electrode 310 covers at least part of the area of the first insulating openings 230 so that heat generated in the operating process of the first electrode 310 can be dissipated in time, preventing the display device in the display panel from aging, and moreover, improving the display reliability of the optical component area.

For example, the second insulating layer 220 is disposed in contact with (is attached to) the first insulating sub-layer 211, and the second insulating layer 220 fills the first insulating openings 230 so as to avoid affecting the overall uniformity of the display panel 10 due to unevenness of the film layer above the first insulating opening 230. Moreover, the first insulating openings 230 are filled with the second insulating layer 220 instead of reserving air. In this manner, the interface thermal resistance between the insulating layer and the air can be eliminated, the heat dissipation capability at the positions of the first insulating openings 230 can be enhanced, and the heat dissipation capability of the entire optical component area 11 can be ensured.

For example, in the thickness direction of the display panel 10, the first electrode 310 at least partially overlaps the first insulating openings 230, that is, the first electrode 310 covers at least part of the first insulating openings 230. In this manner, the first insulating openings 230 are not completely exposed to the light-transmissive area, and no apparent light-transmissive difference in different areas of the optical component area 11 can be caused due to the setting of the first insulating openings, ensuring the light-transmissive effect of the optical component area 11 to be balanced and good.

In summary, in the display panel provided by the embodiments of the present application, the first insulating layer is provided with the at least one first insulating opening, and the second insulating layer is used for filling and covering the first insulating opening. In this manner, isolation interfaces between different films in the area where the first insulating opening is located can be eliminated, the interface thermal resistance of the heat conduction between the first insulating sub-layer and the second insulating layer can be reduced, and the heat conduction capability in the area where the first insulating opening is located can be increased. Moreover, the first electrode and the first insulating opening at least partially overlap. In this manner, heat generated in the operating process of the first electrode can be dissipated in time, preventing the display device in the display panel from aging, and moreover, improving the display reliability of the optical component area. Moreover, the first electrode covers at least part of the first insulating openings so that the first insulating openings are not completely exposed to the light-transmissive area, and no apparent light-transmissive difference in different areas of the optical component area can be caused due to the setting of the first insulating openings, ensuring the light-transmissive effect of the optical component area to be balanced and good.

FIG. 8 is another sectional view taken along direction D-D′ of FIG. 5. As shown in FIG. 8, the first insulating layer 210 further includes at least one second insulating sub-layer 212 located on a side of the first insulating sub-layer 211 facing the substrate 100. One second insulating sub-layer 212 in contact with the first insulating sub-layer 211 is provided with at least one second insulating opening 240. In the thickness direction of the display panel 10, the second insulating opening 240 and the first insulating opening 230 at least partially overlap, and the second insulating layer 220 fills the first insulating opening 230 and the second insulating opening 240.

For example, the first insulating layer 210 is located in both the optical component area 11 and the normal display area. Based on the need to prepare metal films in the normal display area, the first insulating layer 210, as a barrier material, also needs to ensure metals on multiple films to be insulated from each other so that the first insulating layer 210 may include multiple films. As shown in FIG. 8, the first insulating layer 210 may further include at least one second insulating sub-layer 212 that is closer to the substrate 100 than the first insulating sub-layer 211. For example, at least one second insulating sub-layer 212 may be used for insulating the metal films (not shown in FIG. 8) from the substrate 100, and the first insulating sub-layer 211 may be used for insulating different metal films.

For example, the second insulating sub-layer 212 in contact with the first insulating sub-layer 211 is provided with at least one second insulating opening 240. That is, both the first insulating sub-layer 211 and the second insulating sub-layer 212 are provided with the insulating openings so that the interface isolation between the first insulating sub-layer 211 and the second insulating sub-layer 212 can be eliminated, the interface thermal resistance in the optical component area 11 can be better reduced, and the heat dissipation effect in the optical component area 11 can be improved. For example, as shown in FIG. 8, the first insulating layer 210 includes two second insulating sub-layers 212, and a second insulating sub-layer 212 facing the first insulating sub-layer 211 is provided with two second insulating openings 240. The number of second insulating sub-layers 212 and the number of second insulating openings 240 are not limited in the embodiments of the present application.

For example, the first insulating opening 230 and the second insulating opening 240 have overlapping parts. As shown in FIG. 8, the first insulating opening 230 and the second insulating opening 240 completely overlap, or the first insulating opening 230 and the second insulating opening 240 may only have partially overlapping parts (not shown in FIG. 8). The second insulating layer 220 covers and fills the first insulating opening 230 and the second insulating opening 240 through the overlapping parts, ensuring the heat dissipation capability in the optical component area 11, and moreover, better ensuring the evenness of the film above the first insulating opening 230 of the display panel 10.

FIG. 9 is another sectional view taken along direction D-D′ of FIG. 5. Referring to FIG. 9, any one of the second insulating sub-layers 212 is provided with at least one second insulating opening 240.

For example, each of all the second insulating sub-layers 212 is provided with at least one second insulating opening 240. The second insulating layer 220 fills the first insulating opening 230 and the second insulating opening 240, that is, the second insulating layer 220 may extend to the surface of the substrate 100 through the first insulating opening 230 and the second insulating opening 240. In this manner, the interface thermal resistance of any insulating layer at the positions of the insulating opening can be eliminated, the interface thermal resistance in the optical component area 11 can be more effectively reduced, and the heat dissipation effect of the optical component area 11 can be enhanced.

Referring to FIGS. 6 and 7, in the thickness direction of the display panel 10, the first electrode 310 covers the first insulating openings 230.

In the schemes provided by the embodiment of the present application, the first electrode 310 covers above the first insulating openings 230 so that the first insulating openings 230 can more effectively dissipate heat generated by the first electrode 310 to avoid the excessive heat in the optical component area 11 and the service life of the device in the display panel 10 from being affected. Moreover, the first electrode 310 covers the first insulating openings 230, and light is not transmitted to an optical sensor (not shown in the figure) below the substrate 100 through the first insulating openings 230 so that no light-transmissive difference in different areas of the optical component area 11 can be caused due to the setting of the first insulating openings 230, fully ensuring the light-transmissive effect of the optical component area to be balanced and good.

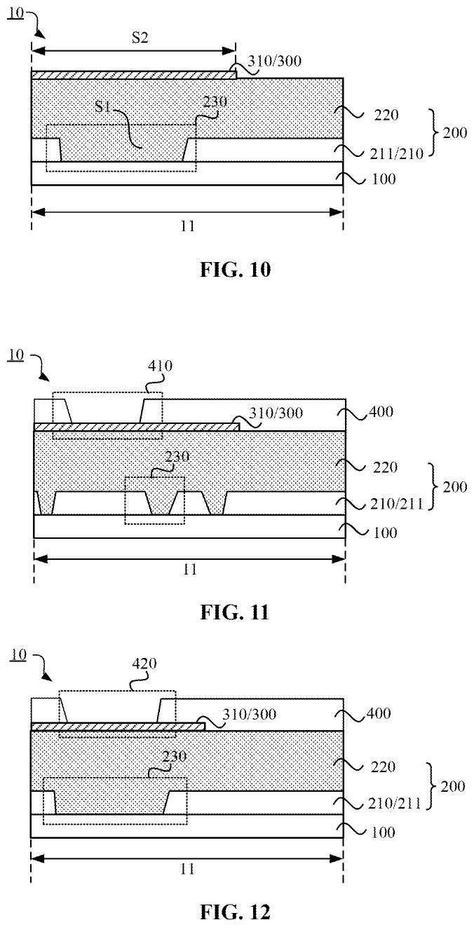

FIG. 10 is another sectional view taken along direction D-D′ of FIG. 5. The first insulating layer 210 is provided with one first insulating opening 230, an opening area of the one first insulating opening 230 is S1, and a coverage area of the one first insulating opening 230 is S2, where 0≤(S2−S1)/S1≤10%.

For example, corresponding to one first electrode 310, the first insulating layer 210 may be provided with only one first insulating opening 230, and the opening area of the provided one first insulating opening 230 is relatively large which, for example, is comparable to the coverage area of the first electrode 310. In this manner, the area of the isolation interfaces between different insulation layers can be reduced to the maximum extent, the interface thermal resistance in the optical component area 11 can be better reduced, and the heat dissipation efficiency of the optical component area 11 can be improved. Moreover, the one first insulation opening 230 having a relatively large opening area is provided. In this manner, only one insulating opening needs to be prepared so that the preparation process of the insulating opening is simpler.

For example, the opening area of the first insulating opening 230 is comparable to the coverage area of the first electrode 310. It can be understood that the opening area of S1 of the first insulating opening 230 and the coverage area of S2 of the first electrode 310 satisfy 0≤(S2−S1)/S1≤10%. In this manner, it is ensured that the opening area of the first insulating opening 230 in the optical component area 11 is the same as or similar to the opening area of the first electrode 310, that the first insulating opening 230 effectively and fully dissipates the heat generated by the first electrode 310, and moreover, that the preparation process of the insulating opening is simple.

FIG. 11 is another sectional view taken along direction D-D′ of FIG. 5. As shown in FIG. 11, the display panel 10 further includes a pixel defining layer 400 located on the side of the second insulating layer 220 facing away from the substrate 100, where the pixel defining layer 400 is provided with a first pixel opening 410, and the first pixel opening 410 exposes the first electrode 310. In the thickness direction of the display panel 10, the first pixel opening 410 and the first insulating opening 230 do not overlap.

For example, the display panel 10 may further include the pixel defining layer 400 including the first pixel opening 410, and the first pixel opening 410 exposes the first electrode 310. Moreover, the light-emitting material in the light-emitting element may be correspondingly disposed in the first pixel opening 410 and defines a light-emitting area through the first pixel opening 410.

For example, the first insulating layer 210 includes at least one first insulating opening 230. The first insulating openings 230 are arranged below the first electrode 310. For the first electrode 310, the setting of the first insulating opening 230 may inevitably cause unevenness between the disposition area of the first insulating openings 230 and the non-disposition area of the first insulating openings 230 to degrees. For the area corresponding to the first pixel opening 410, the unevenness of the first electrode 310 causes different light-emitting paths in different areas, affecting the display effect. Therefore, in the embodiments of the present application, in the thickness direction of the display panel 10, the first pixel opening 410 and the first insulating opening 230 do not overlap, that is, the first pixel opening 410 is not located in the area where the first insulating opening 230 is disposed, as shown in FIG. 11. In this manner, it is ensured that the films below the first pixel opening 410 are good in consistency and evenness and that the optical paths of the display light are consistent and the display effect is good.

FIG. 12 is another sectional view taken along direction D-D′ of FIG. 5. As shown in FIG. 12, the display panel 10 further includes a pixel defining layer 400 located on the side of the second insulating layer 220 facing away from the substrate 100, where the pixel defining layer 400 is provided with a second pixel opening 420, and the second pixel opening 420 exposes the first electrode 310. In the thickness direction of the display panel 10, the first insulating opening 230 covers the second pixel opening 420.

As described above, for the area corresponding to the first pixel opening 410, the unevenness of the first electrode 310 causes different light-emitting paths in different areas, affecting the display effect. Therefore, in the embodiments of the present application, in the thickness direction of the display panel 10, the first insulating opening 230 may cover the second pixel opening 420, that is, the second pixel opening 420 is fully disposed in the area of the first insulating opening 230, as shown in FIG. 12. In this manner, it is ensured that the films below the second pixel opening 420 are good in consistency and evenness and that the optical paths of the display light are consistent and the display effect is good. For example, a pixel circuit electrically connected to the first electrode 310 is not disposed in the optical component area 11.

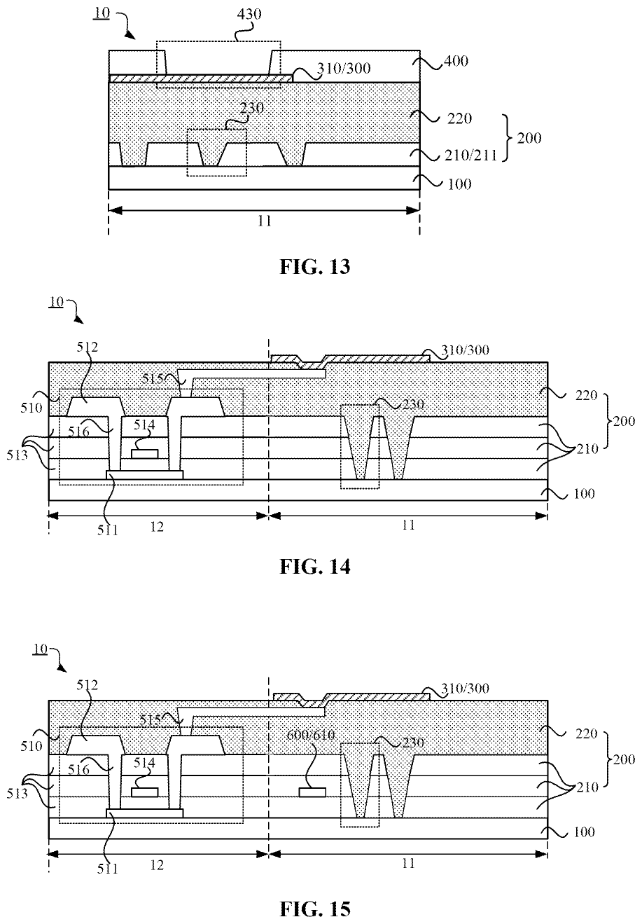

FIG. 13 is another sectional view taken along direction D-D′ of FIG. 5. As shown in FIG. 13, the display panel 10 also includes a pixel defining layer 400 located on the side of the second insulating layer 220 facing away from the substrate 100, where the pixel defining layer 400 is provided with a third pixel opening 430 from which the first electrode 310 is exposed. In the thickness direction of the display panel 10, the third pixel opening 430 and the first insulating openings 230 partially overlap.

For example, the third pixel opening 430 and the first insulating openings 230 partially overlap, and moreover, the third pixel opening 430 partially overlaps part of an area of the first insulating layer 210 where no first insulating openings 230 are disposed, as shown in FIG. 13. In this manner, the position relationship between the third pixel opening 430 and the first insulating openings 230 is simple and flexible. When the third pixel opening 430 is provided, it is not needed to additionally consider the disposition position, and the disposition manner of the third pixel opening 430 is flexible and simple.

FIG. 14 is a sectional view taken along direction E-E′ of FIG. 5. Referring to FIGS. 5 and 14, the display panel 10 further includes a first pixel circuit 510 electrically connected to the first electrode 310. The first pixel circuit 510 includes a thin film transistor including an active layer 511, a source-drain electrode 512, and interlayer insulating layers 513 between the active layer 511 and the source-drain electrode 512, where a source-drain via 516 is formed in the interlayer insulating layers 513, and the source-drain electrode 512 is electrically connected to the active layer 511 through the source-drain via 516. The first insulating layer 210 includes the interlayer insulating layers 513, and the first insulating opening 230 includes a via prepared in the same process as the source-drain via 516.

For example, the display panel 10 further includes the first pixel circuit 510. The first pixel circuit 510 is electrically connected to the first electrode 310 and configured to drive a first light-emitting element 300 in the display panel 10 to emit light. For example, the first pixel circuit 510 may be located outside the optical component area 11. For example, as shown in FIG. 14, the first pixel circuit 510 may be located in the normal display area 12, and the electrical connection between the first electrode 310 and the first pixel circuit 510 may be achieved through a connection structure 515, thereby driving the first light-emitting element 300 to emit the light.

For example, the pixel circuit 510 may include one thin film transistor (for example, a liquid crystal display panel or an electronic paper is selected as the display panel), and may include multiple thin film transistors and at least one storage capacitor (for example, an OLED display panel or a Micro-LED display panel is selected as the display panel), such as seven thin film transistors and one storage capacitor (7T1C). The specific structure of the pixel circuit is not limited by the embodiments of the present application. As shown in FIG. 14, the thin film transistor may include the active layer 511, the source-drain electrode 512, the gate 514 and the interlayer insulating layers 513 between the active layer 511 and the source-drain electrode 512. The source-drain via 516 passes through the interlayer insulating layers 513 to achieve the electrical connection between the source-drain electrode 512 and the active layer 511. As shown in FIG. 14, the first insulating layer 210 includes the interlayer insulating layers 513. The via is prepared in the interlayer insulating layers 513 to achieve the electrical connection between the source-drain electrode 512 and the active layer 511, and the first insulating openings 230 are prepared in the first insulating layer 210 in the optical component area 11 to achieve the improvement of the heat dissipation performance. For example, the first insulating openings 230 and the source-drain via 516 may be prepared in the same via preparation technique and there is no need to increase a mask technique separately, saving the costs and improving the preparation convenience of the display panel 10.

FIG. 15 is another sectional view taken along direction E-E′ of FIG. 5. As shown in FIG. 15, the optical component area 11 may further include a compensation structure 600 including at least one compensation film 610. In the thickness direction of the display panel 10, the first electrode 310 and the compensation structure 600 at least partially overlap.

For example, the optical component area 11 may further include the compensation structure 600 including at least one compensation film 610, where the compensation structure 600 compensates for the heat dissipation capability of the optical component area 11. The first insulating openings 230 and the compensation structure 600 are both disposed in the optical component area 11 so that a good heat dissipation effect of the optical component area 11 can be more effectively ensured. It is to be noted that an example where the compensation structure 600 includes only one compensation film 610 in FIG. 15 is used for illustration. It is to be understood that the compensation structure 600 may also include two compensation films (not shown in FIG. 15), and the specific number of compensation films 610 is not limited in the embodiments of the present application.

For example, referring to FIG. 15, the compensation structure 600 is located on a side of the first electrode 310 facing the substrate 100. In the thickness direction of the display panel 10, the first electrode 310 and the compensation structure 600 at least partially overlap to ensure that the compensation structure 600 can dissipate the heat generated in the working process of the first electrode 310 in time, so as to improve the heat dissipation effect of the optical component area 11.

For example, the compensation structure 600 may be unconnected to circuit elements, i.e., potentially suspended, and no voltage signal is applied in the compensation structure 600 without regard to the signal interference. The potentially suspended compensation structure 600 is provided so that the heat dissipation capability of the optical component area 11 can be improved. For example, since the compensation structure 600 is potentially suspended and is connected to no circuit elements, the arrangement of the compensation structure 600 is simple. Moreover, since the compensation structure 600 is potentially suspended, the arrangement of the compensation structure 600 does not interfere with the normal light-emitting display of the first light-emitting element 300 so that a good display effect of the first light-emitting element 300 in the optical component area 11 can be ensured.

Referring to FIG. 15, the first electrode 310 covers the compensation structure 600.

For example, the compensation structure 600 is disposed in the optical component area 11 to dissipate the heat generated in the optical component area 11. The first electrode 310 covers the compensation structure 600, ensuring that the arrangement of the compensation structure 600 does not affect the light-transmissive effect of the optical component area 11, and that the light-transmissive effect of the optical component area 11 is good.

For example, referring to FIG. 15, the compensation film 610 includes a metal compensation film.

For example, the compensation film 610 may be the metal compensation film. The metal film has a better heat dissipation effect, thereby improving the heat dissipation capability of the compensation structure 600, and improving the heat dissipation effect of the optical component area 11.

Referring to FIG. 15, the display panel 10 further includes a first pixel circuit 510. The first pixel circuit 510 is electrically connected to the first electrode 310. The first pixel circuit 510 includes a thin film transistor including a gate 514 and a source-drain electrode 512. The metal compensation film and the gate 514 and/or the source-drain electrode 512 are disposed in the same layer.

For example, the first pixel circuit 510 is electrically connected to the first electrode 310 and is configured to drive the first light-emitting element 300 in the display panel 10 to emit light. The first pixel circuit 510 includes the thin film transistor. As shown in FIG. 15, the thin film transistor includes the source-drain electrode 512 and the gate 514 that are disposed at different films. The compensation structure 600 may be one film, or multi-layer films disposed on different films.

For example, the compensation film 610 includes the metal compensation film that may be disposed in the same layer as the source-drain electrode 512 and/or the gate 514. For example, the metal compensation film may be disposed in the same layer as the gate 514, as shown in FIG. 15; the metal compensation film may also be disposed in the same layer as the source-drain electrode 512 (not shown in the figure); and the metal compensation film may also be disposed in the same layer as both the gate 514 and the source-drain electrode 512 (not shown in the figure). The metallic metal compensation film is disposed in the same layer as the source-drain electrode 512 and the gate 512, improving the heat dissipation effect of the optical component area 11 while ensuring the film structure of the display panel to be simple and the preparation technique of the metal compensation film to be simple.

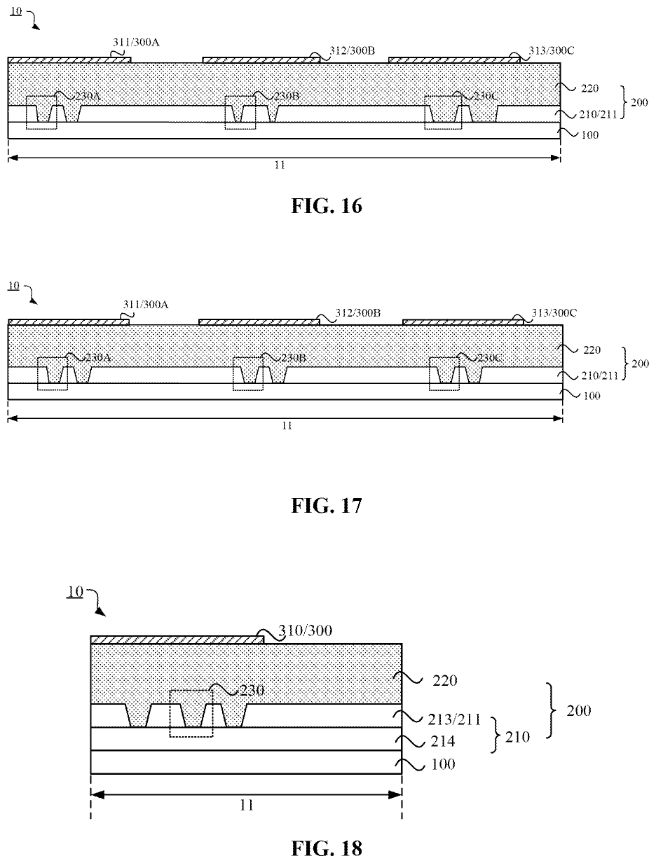

FIG. 16 is a sectional view taken along direction F-F′ of FIG. 5. As shown in FIG. 16, the display panel 10 includes first light-emitting elements 300, where the first light-emitting element 300 includes the first electrode 310, and the first light-emitting elements 300 include a first red light-emitting element 300A, a first green light-emitting element 300B and a first blue light-emitting element 300C. The first red light-emitting element 300A includes a first red electrode 311, the first green light-emitting element 300B includes a first green electrode 312, and the first blue light-emitting element 300C includes a first blue electrode 313. The first insulating openings 230 include first insulating sub-openings 230A, second insulating sub-openings 230B and third insulating sub-openings 230C. In the thickness direction of the display panel 10, the first red electrode 311 and the first insulating sub-openings 230A at least partially overlap, the first green electrode 312 and the second insulating sub-openings 230B at least partially overlap, and the first blue electrode 313 and the third insulating sub-openings 230C at least partially overlap. An opening area sum of all the third insulating sub-openings 230C is greater than an opening area sum of all the first insulating sub-openings 230A, the opening area sum of all the first insulating sub-openings 230A is greater than an opening area sum of all the second insulating sub-openings 230B.

For example, in the thickness direction of the display panel 10, the first red electrode 311 and the first insulating sub-openings 230A at least partially overlap, the first green electrode 312 and the second insulating sub-openings 230B at least partially overlap, and the first blue electrode 313 and the third insulating sub-openings 230C at least partially overlap. That is, the vertical projection of the first red electrode 311 on the plane where the substrate 100 is located covers at least part of the first insulating sub-openings 230A, the vertical projection of the first green electrode 312 on the plane where the substrate 100 is located covers at least part of the second insulating sub-openings 230B, and the vertical projection of the first blue electrode 313 on the plane where the substrate 100 is located covers at least part of the third insulating sub-openings 230C. In this way, it is ensured that the first insulating sub-openings 230A dissipate the heat generated by the first red electrode 311, the second insulating sub-openings 230B dissipate the heat generated by the first green electrode 312, and the third insulating sub-openings 230C dissipate the heat generated by the first blue electrode 313 so that the heat generated by the first red light-emitting element 300A, the first green light-emitting element 300B, and the first blue light-emitting element 300C can be well dissipated, thereby ensuring a good heat dissipation effect of the optical component area 11.

For example, in the display process of the display panel 10, the blue light-emitting element produces the most heat, the red light-emitting element is the second, and the green light-emitting element produces the least heat, so the opening area sum of all the third insulating sub-openings 230C corresponding to one first blue light-emitting element 300C can be set to be the greatest, that is, the interface thermal resistance reduced in the third insulating sub-opening 230C is the greatest, ensuring the heat dissipation effect of the third insulating sub-openings 230C to be the best. For example, the opening area sum of all the first insulating sub-openings 230A corresponding to one first red light-emitting element 300A can be set to be the second, and the opening area sum of all the second insulating sub-openings 230B corresponding to one first green light-emitting element 300B can be set to be the least, that is, the opening area sum of the first insulating openings 230 is set differently according to the heat generation of the light-emitting elements corresponding to the first insulating openings 230, ensuring that different first light-emitting elements 300 correspond to the matching first insulating openings 230, that the heat dissipation effect of the optical component area 11 is balanced, and that the first light-emitting elements 300 in the optical component area 11 have a good light-emitting effect.

FIG. 17 is another sectional view taken along direction F-F′ of FIG. 5. As shown in FIG. 17, the display panel 10 includes first light-emitting elements 300, where the first light-emitting element 300 includes the first electrode 310, and the first light-emitting elements 300 include a first red light-emitting element 300A, a first green light-emitting element 300B and a first blue light-emitting element 300C. The first red light-emitting element 300A includes a first red electrode 311, the first green light-emitting element 300B includes a first green electrode 312, and the first blue light-emitting element 300C includes a first blue electrode 313. The first insulating openings 230 include first insulating sub-openings 230A, second insulating sub-openings 230B and third insulating sub-openings 230C. In the thickness direction of the display panel 10, the first red electrode 311 and the first insulating sub-openings 230A at least partially overlap, the first green electrode 312 and the second insulating sub-openings 230B at least partially overlap, and the first blue electrode 313 and the third insulating sub-openings 230C at least partially overlap. An opening area sum of all the first insulating sub-openings 230A, an opening area sum of all the second insulating sub-openings 230B and an opening area sum of all the third insulating sub-openings 230C are same.

For example, in the thickness direction of the display panel 10, the first red electrode 311 and the first insulating sub-openings 230A at least partially overlap, the first green electrode 312 and the second insulating sub-openings 230B at least partially overlap, and the first blue electrode 313 and the third insulating sub-openings 230C at least partially overlap. That is, the vertical projection of the first red electrode 311 on the plane where the substrate 100 is located covers at least part of the first insulating sub-openings 230A, the vertical projection of the first green electrode 312 on the plane where the substrate 100 is located covers at least part of the second insulating sub-openings 230B, and the vertical projection of the first blue electrode 313 on the plane where the substrate 100 is located covers at least part of the third insulating sub-openings 230C. In this way, it is ensured that the first insulating sub-openings 230A dissipate the heat generated by the first red electrode 311, the second insulating sub-openings 230B dissipate the heat generated by the first green electrode 312, and the third insulating sub-openings 230C dissipate the heat generated by the first blue electrode 313 so that the heat generated by the first red light-emitting element 300A, the first green light-emitting element 300B, and the first blue light-emitting element 300C can be well dissipated, thereby ensuring a good heat dissipation effect of the optical component area 11.

For example, the opening area sum of all the first insulating sub-openings 230A corresponding to one first red light-emitting element 300A, the opening area sum of all the second insulating sub-openings 230B corresponding to one first green light-emitting element 300B, and the opening area sum of all the third insulating sub-openings 230C corresponding to one first blue light-emitting element 300C are the same so that the first insulating sub-opening 230A, the second insulating sub-opening 230B and the third insulating sub-opening 230C can be prepared together in the same preparation manner. That is, the preparation manner of the first insulating openings 230 is simple, and the heat dissipation effect in different areas of the optical component area 11 is balanced.

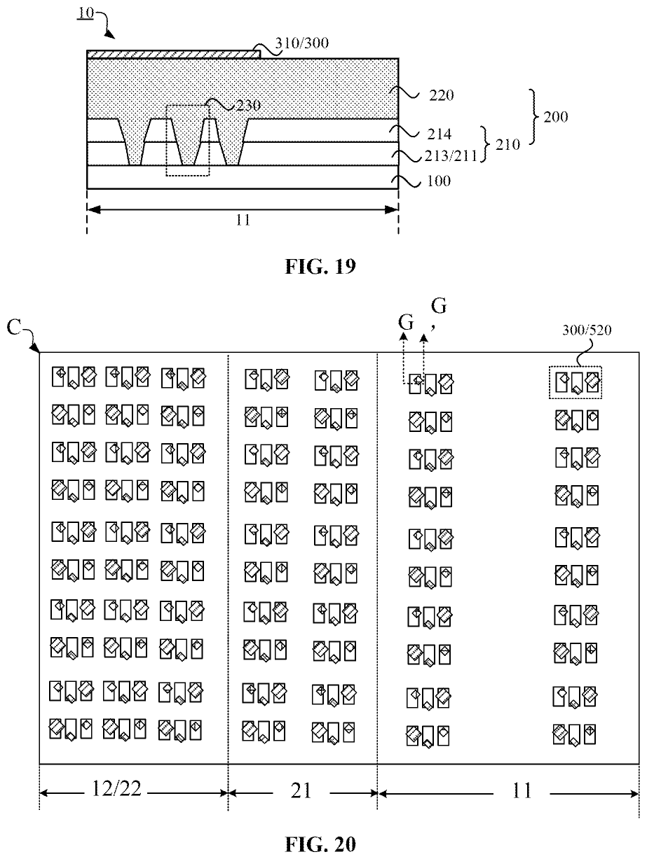

FIG. 18 is another sectional view taken along direction D-D′ of FIG. 5. FIG. 19 is another sectional view taken along direction D-D′ of FIG. 5. As shown in FIGS. 18 and 19, the first insulating layer 210 further includes a third insulating sub-layer 213 and a fourth insulating sub-layer 214. The compactness of the third insulating sub-layer 213 is greater than the compactness of the fourth insulating sub-layer 214. The third insulating sub-layer 213 or the first insulating layer 210 between the third insulating sub-layer 213 and the second insulating layer 220 is provided with the insulating opening.

Here, the first insulating layer 210 further includes the third insulating sub-layer 213 and the fourth insulating sub-layer 214 that have different compactness. For example, the compactness of the third insulating sub-layer 213 is greater than the compactness of the fourth insulating sub-layer 214. For example, the third insulating sub-layer 213 having relatively large compactness is provided with the insulating openings, reducing the effect of the insulating layer having relatively large compactness on the heat dissipation, ensuring the interface thermal resistance of the optical component area 11, and improving the heat dissipation effect of the optical component area 11.

For example, as shown in FIG. 18, the third insulating sub-layer 213 faces the second insulating layer 220. Here, the third insulating sub-layer 213 may be the first insulating sub-layer 211. The first insulating openings 230 are provided in the third insulating layer 213 and are filled with the second insulating layer 220, reducing the thermal resistance of the heat conduction between films, improving the heat dissipation capability in the area where the first insulating openings 230 are located, improving the heat dissipation capability of the optical component area 11, and thus preventing the device from thermal aging.

For example, as shown in FIG. 19, the fourth insulating sub-layer 214 faces the second insulating layer 220. Here, the third insulating sub-layer 213 may be the first insulating sub-layer 211. The first insulating openings 230 are provided in the third insulating layer 213, and moreover, the insulating openings corresponding to the positions of the first insulating openings 230 in the third insulating sub-layer 213 are provided in the fourth insulating sub-layer 214, ensuring the first insulating openings 230 to be filled with the second insulating layer 220, thereby reducing the thermal resistance of the heat conduction between films, improving the heat dissipation capability in the area where the first insulating openings 230 are located, improving the heat dissipation capability of the optical component area 11, and thus preventing the device from thermal aging.

As shown in FIGS. 6 to 19, the second insulating layer 220 is in contact with the first electrode 310.

For example, since the second insulating layer 220 covers the first insulating openings 230 so that the contact interface between the second insulating layer 220 and the first insulating sub-layer 211 can be reduced, and the interface thermal resistance during the heat transfer can be reduced. Moreover, the second insulating layer 220 is in contact with the first electrode 310, and the heat generated in the operating process of the first electrode 310 can be directly conducted through the second insulating layer 220 so that the heat dissipation can be more effectively performed on the first electrode 310, thereby improving the heat dissipation effect of the optical component area 11.

For example, the second insulating layer 220 is a planarization layer.

For example, the second insulating layer 220 is the planarization layer so that a planarized film structure can be better provided for the first electrode 310 to ensure the first electrode 310 to be flat. In this manner, light-emitting paths of the first light-emitting element 300 in different areas can be same or similar, ensuring the display effect of the display panel. For example, since the planarization layer is generally an organic film, the second insulating layer 220 is configured to be the planarization layer, so it is also feasible to ensure that the second insulating layer 220 has a relatively large thickness and that the second insulating layer 220 can fill the first insulating openings 230. In this manner, the interface thermal resistance between the insulating layer and the air will not be formed due to the first insulating openings 230 being partially filled, ensuring a good heat dissipation effect of the optical component area.

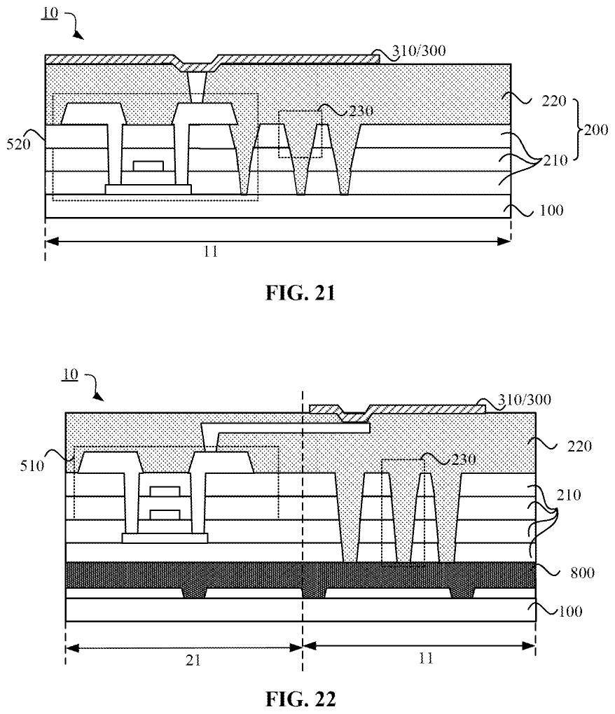

FIG. 20 is another enlarged view of part C of FIG. 4. FIG. 21 is a sectional view taken along direction G-G′ of FIG. 20. As shown in FIGS. 20 and 21, the display panel 10 further includes a pixel circuit, where the pixel circuit includes a second pixel circuit 520 located in the optical component area 11 and electrically connected to the first electrode 310. In the thickness direction of the display panel 10, the second pixel circuit 520 and the first insulating openings 230 at least partially overlap.

For example, the second pixel circuit 520 is located in the optical component area 11, electrically connected to the first electrode 310, and is configured to drive the first light-emitting element 300 in the display panel 10 to emit light.

For example, in the thickness direction of the display panel 10, the second pixel circuit 520 and the first insulating openings 230 at least partially overlap. That is, the second pixel circuit 520 covers part of the first insulating openings 230, as shown in FIG. 21. The first insulating openings 230 also dissipate the heat generated by the second pixel circuit 520 while dissipating the heat generated by the first electrode 310, improving the stability of the second pixel circuit 520.

FIG. 22 is another sectional view taken along direction E-E′ of FIG. 5. As shown in FIG. 22, the display panel 10 further includes at least one thermal conductive bridge 800 in contact with the second insulating layer 220.

For example, in the schemes provided by the embodiments of the present application, the display panel 10 further includes at least one thermal conductive bridge 800 that is connected to the second insulating layer 220 through the first insulating openings 230 so that the heat generated in the optical component area 11 can be transversely transferred, for example, to an area other than the optical component area 11; or can be used for balancing the heat generated in the optical component area 11 to ensure the heat within the optical component area 11 to be uniform.

Referring to FIGS. 5 and 22, the display panel 10 further includes a first display area 21 and a second display area 22, where the first display area 21 surrounds at least part of the optical component area 11, and the second display area 22 surrounds at least part of the first display area 21. In the thickness direction of the display panel 10, the thermal conductive bridge 800 overlaps the first display area 21 and/or the second display area 22.

For example, as shown in FIG. 5, the display panel 10 includes the optical component area 11, the first display area 21 and the second display area 22. The first display area 21 surrounds at least part of the optical component area 11, and the second display area 22 surrounds at least part of the first display area 21. Here, the first display area 21 may be understood as a transition display area, and the second display area 22 may be understood as a normal display area 12. Generally, the optical component area 11 can be used as a high-light-transmissive display area, and the transition display area can be used for providing the pixel circuits electrically connected to the light-emitting elements in the optical component area and/or for achieving a gradual change in the density of the light-emitting elements between the normal display area and the optical component area.

For example, as shown in FIG. 22, in the thickness direction of the display panel 10, the thermal conductive bridge 800 overlaps both the first display area 21 and the second display area 22. For example, the thermal conductive bridge 800 may also overlap only the first display area 21. The thermal conductive bridge 800 is provided so that the heat generated by the optical component area 11 that generates more heat can be transversely transferred to the first display area 21 and the second display area 22 to balance the heat within the display panel 10.

Referring to FIG. 6, the first insulating sub-layer 211 is provided with multiple first insulating openings 230. In different unit areas, the maximum value of an opening area sum of the first insulating openings 230 is S3 and the minimum value of the opening area sum of the first insulating openings 230 is S4, where (S3−S4)/S3≤20%.

Here, the first insulating sub-layer 211 may be provided with multiple first insulating openings 230 so that the heat dissipation capability of the optical component area 11 can be more effectively improved. For example, in the unit area, the maximum value of the opening area sum of the first insulating openings 230 is S3 and the minimum value of the opening area sum of the first insulating openings 230 is S4, where (S3−S4)/S3≤20%. In this manner, in different unit areas of the first insulating sub-layer 211, the opening area sums of the first insulating openings 230 can be ensured to be same or similar, and the heat dissipation effect in different areas of the optical component area 11 can be ensured to be same or similar, thereby ensuring the overall heat dissipation effect of the optical component area 11 to be balanced.

Referring to FIG. 6, the substrate 100 is embedded with dopant particles 700, the thermal conductivity of the dopant particles 700 is greater than the thermal conductivity of the material of the substrate 100. In the schemes provided by the embodiments of the present application, the substrate 100 is embedded with the dopant particles 700, such as graphite particles having the thermal conductivity greater than the thermal conductivity of the material of the substrate 100, improving the thermal conductivity of the substrate 100, and facilitating improving the heat dissipation effect of the optical component area 11.

Referring to FIGS. 6 and 9, the substrate 100 is exposed by the insulating openings in the first insulating layer 210, and the second insulating layer 220 covers the insulating openings and is in contact with the substrate 100. In the schemes provided by the embodiments of the present application, the insulating openings are added to the first insulating layer 210, improving the heat dissipation effect of the optical component area 11. For example, as shown in FIG. 6, if only the first insulating sub-layer 211 is provided, the insulating openings are the first insulating openings 230. As shown in FIG. 9, if the second insulating sub-layer 212 is further provided, the insulating openings are the first insulating openings 230 and the second insulating openings 240.

For example, the insulating openings provided in the first insulating layer 210 are in direct contact with the substrate 100. The substrate 100 is embedded with the dopant particles 700 having a relatively great thermal conductivity so that the heat dissipation effect of the optical component area 11 can be improved.

As shown in FIGS. 5 and 14, the display panel 10 further includes the first display area 21 and the second display area 22. The first display area 21 surrounds at least part of the optical component area 11, and the second display area 22 surrounds at least part of the first display area 21. The display panel 10 further includes a pixel circuit, and the pixel circuit includes a first pixel circuit 510, where the first pixel circuit 510 is located in the first display area 21 and is electrically connected to the first electrode 310.

The first pixel circuit 510 is electrically connected to the first electrode 310 and is configured to drive the first light-emitting element 300 in the display panel 10 to emit light. For example, as shown in FIG. 14, the first pixel circuit 510 may be located in the first display area 12, and the first electrode 310 located in the optical component area 11 is electrically connected to the first pixel circuit 510 in the first display area 12 through a connection structure 515, thereby achieving the light emitting of the first light-emitting element 300. Moreover, the pixel circuit is disposed in the first display area 21, so it is also feasible to ensure the optical component area 11 to have more light-transmissive areas, and to ensure a good light-transmissive effect of the optical component area 11.

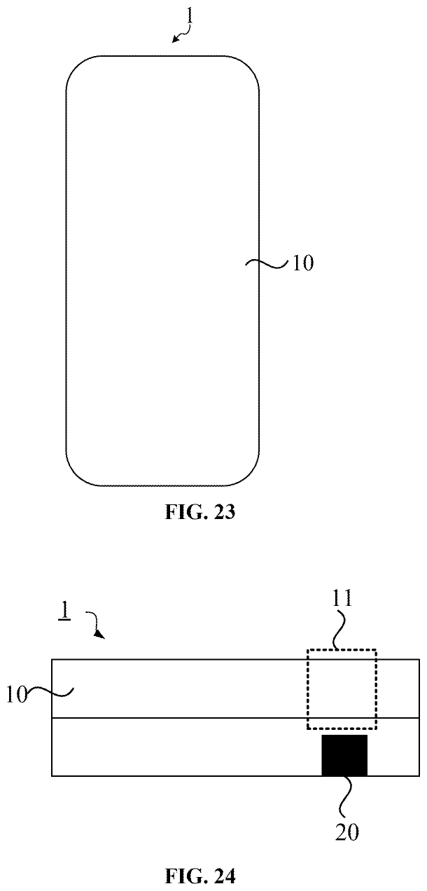

Based on the same inventive concept, embodiments of the present application further provide a display device. FIG. 23 is a structural diagram of a display device according to an embodiment of the present application. As shown in FIG. 23, a display device 1 includes the display panel 10 according to any embodiment of the present application. Therefore, the display device 1 provided by the embodiments of the present application has the technical effects of the solutions of any one of the embodiments described above, and structures which are the same as or correspond to the structures in the embodiments described above and the explanation of the terms will not be repeated herein. The display device 1 provided by the embodiments of the present application may be the phone shown in FIG. 24 and may be any electronic product with a display function, including but not limited to a television, a laptop, a desktop display, a tablet computer, a digital camera, a smart bracelet, smart glasses, an in-vehicle display, a medical display, industry-controlling equipment, a touch interactive terminal and the like, and is not specifically limited in the embodiments of the present application.

FIG. 24 is a sectional view of a display device provided by an embodiment of the present application. As shown in FIGS. 23 and 24, for example, the display device provided by an embodiment of the present application further includes a sensor 20 disposed corresponding to the optical component area 11.

The sensor 20 may include any photosensitive element such as a camera, an infrared sensor, and the like. The sensor 20 is disposed corresponding to the optical component area 11, ensuring that the sensor 20 can normally receive light and normally operate while having a display function.

1. A display panel, comprising: an optical component area, wherein the optical component area comprises a substrate, an insulating layer and a first electrode,
wherein the insulating layer comprises a first insulating layer and a second insulating layer, the second insulating layer is located on a side of the first insulating layer facing away from the substrate, and the first insulating layer comprises a first insulating sub-layer in contact with the second insulating layer; and
wherein the first electrode is located on a side of the second insulating layer facing away from the substrate; the first insulating sub-layer is provided with at least one first insulating opening; and in a thickness direction of the display panel, the second insulating layer covers the at least one first insulating opening, and the first electrode and the at least one first insulating opening at least partially overlap.

2. The display panel according to claim 1, wherein the first insulating layer further comprises at least one second insulating sub-layer located on a side of the first insulating sub-layer facing the substrate;
wherein one second insulating sub-layer at least in contact with the first insulating sub-layer is provided with at least one second insulating opening, and in the thickness direction of the display panel, the at least one second insulating opening and the at least one first insulating opening at least partially overlap; and
the second insulating layer fills the at least one first insulating opening and the at least one second insulating opening.

3. The display panel according to claim 2, wherein one second insulating sub-layer of the at least one second insulating sub-layer is provided with at least one second insulating opening.

4. The display panel according to claim 1, wherein in the thickness direction of the display panel, the first electrode covers the at least one first insulating opening.

5. The display panel according to claim 4, wherein the first insulating layer is provided with one first insulating opening, an opening area of the one first insulating opening is S1, and a coverage area of the first electrode is S2, wherein 0≤(S2−S1)/S1≤10%.

6. The display panel according to claim 1, further comprising: a pixel defining layer located on the side of the second insulating layer facing away from the substrate, wherein the pixel defining layer is provided with a first pixel opening, and the first pixel opening exposes the first electrode; and
in the thickness direction of the display panel, the first pixel opening and the at least one first insulating opening do not overlap.

7. The display panel according to claim 1, further comprising: a pixel defining layer located on the side of the second insulating layer facing away from the substrate, wherein the pixel defining layer is provided with a second pixel opening, and the second pixel opening exposes the first electrode; and
in the thickness direction of the display panel, the at least one first insulating opening covers the second pixel opening.

8. The display panel according to claim 1, further comprising: a pixel defining layer located on the side of the second insulating layer facing away from the substrate, wherein the pixel defining layer is provided with a third pixel opening, and the third pixel opening exposes the first electrode; and
in the thickness direction of the display panel, the third pixel opening and the at least one first insulating opening partially overlap.

9. The display panel according to claim 1, further comprising: a first pixel circuit electrically connected to the first electrode,
wherein the first pixel circuit comprises a thin film transistor, the thin film transistor comprises an active layer, a source-drain electrode, and an interlayer insulating layer located between the active layer and the source-drain electrode, wherein the interlayer insulating layer is provided with a source-drain via, and the source-drain electrode is electrically connected to the active layer through the source-drain via; and
the first insulating layer comprises the interlayer insulating layer, and the at least one first insulating opening comprises a via prepared in a same process as the source-drain via.

10. The display panel according to claim 1, wherein the optical component area further comprises a compensation structure comprising at least one compensation film, wherein in the thickness direction of the display panel, the first electrode and the compensation structure at least partially overlap.

11. The display panel according to claim 10, wherein the first electrode covers the compensation structure.

12. The display panel according to claim 10, wherein the at least one compensation film comprises a metal compensation film.

13. (canceled)

14. The display panel according to claim 1, wherein the display panel further comprises a first light-emitting element, and the first light-emitting element comprises the first electrode,
wherein the first light-emitting element comprises a first red light-emitting element, a first green light-emitting element, and a first blue light-emitting element;
the first red light-emitting element comprises a first red electrode, the first green light-emitting element comprises a first green electrode, and the first blue light-emitting element comprises a first blue electrode;
the at least one first insulating opening comprises at least one first insulating sub-opening, at least one second insulating sub-opening, and at least one third insulating sub-opening;
in the thickness direction of the display panel, the first red electrode and the at least one first insulating sub-opening at least partially overlap, the first green electrode and the at least one second insulating sub-opening at least partially overlap, and the first blue electrode and the at least one third insulating sub-opening at least partially overlap; and
an opening area sum of the at least one third insulating sub-opening is greater than an opening area sum of the least one first insulating sub-opening, the opening area sum of the at least one first insulating sub-opening is greater than an opening area sum of the at least one second insulating sub-opening.

15. The display panel according to claim 1, wherein the display panel further comprises a first light-emitting element, and the first light-emitting element comprises the first electrode,
wherein the first light-emitting element comprises a first red light-emitting element, a first green light-emitting element, and a first blue light-emitting element;
the first red light-emitting element comprises a first red electrode, the first green light-emitting element comprises a first green electrode, and the first blue light-emitting element comprises a first blue electrode;
the at least one first insulating opening comprises at least one first insulating sub-opening, at least one second insulating sub-opening, and at least one third insulating sub-opening;
in the thickness direction of the display panel, the first red electrode and the at least one first insulating sub-opening at least partially overlap, the first green electrode and the at least one second insulating sub-opening at least partially overlap, and the first blue electrode and the at least one third insulating sub-opening at least partially overlap; and
an opening area sum of the at least one first insulating sub-opening, an opening area sum of the at least one second insulating sub-opening, and an opening area sum of the at least one third insulating sub-opening are the same.

16. The display panel according to claim 1, wherein the first insulating layer further comprises a third insulating sub-layer and a fourth insulating sub-layer, and compactness of the third insulating sub-layer is greater than compactness of the fourth insulating sub-layer; and
at least the third insulating sub-layer and the first insulating layer located between the third insulating sub-layer and the second insulating layer is provided with at least one insulating opening.

17. The display panel according to claim 1, wherein the second insulating layer is in contact with the first electrode.

18. (canceled)

19. The display panel according to claim 1, further comprising: a pixel circuit, wherein the pixel circuit comprises a second pixel circuit located in the optical component area and electrically connected to the first electrode; and
in the thickness direction of the display panel, the second pixel circuit and the at least one first insulating opening at least partially overlap.

20. The display panel according to claim 1, further comprising: at least one thermal conductive bridge in contact with the second insulating layer.

21. The display panel according to claim 20, further comprising: a first display area and a second display area,
wherein the first display area surrounds at least part of the optical component area, and the second display area surrounds at least part of the first display area; and
in the thickness direction of the display panel, the thermal conductive bridge overlaps at least one of the first display area or the second display area.

22. The display panel according to claim 1, wherein the first insulating sub-layer is provided with a plurality of first insulating openings;
in different unit areas, a maximum value of an opening area sum of the plurality of first insulating openings is S3 and a minimum value of the opening area sum of the plurality of first insulating openings is S4, wherein (S3−S4)/S3≤20%.

23. The display panel according to claim 1, wherein the substrate is embedded with dopant particles, wherein a thermal conductivity of the dopant particles is greater than a thermal conductivity of a material of the substrate.

24. (canceled)

25. The display panel according to claim 1, further comprising: a first display area and a second display area,
wherein the first display area surrounds at least part of the optical component area, and the second display area surrounds at least part of the first display area; and
the display panel further comprises a pixel circuit, wherein the pixel circuit comprises a first pixel circuit, and the first pixel circuit is located in the first display area and is electrically connected to the first electrode.

26. A display device, comprising: a display panel, wherein the display panel comprises an optical component area, wherein the optical component area comprises a substrate, an insulating layer and a first electrode,
wherein the insulating layer comprises a first insulating layer and a second insulating layer, the second insulating layer is located on a side of the first insulating layer facing away from the substrate, and the first insulating layer comprises a first insulating sub-layer in contact with the second insulating layer; and
wherein the first electrode is located on a side of the second insulating layer facing away from the substrate; the first insulating sub-layer is provided with at least one first insulating opening; and in a thickness direction of the display panel, the second insulating layer covers the at least one first insulating opening, and the first electrode and the at least one first insulating opening at least partially overlap.

27. (canceled)
